(19) United States
(12) Patent Application Publication
(10) Pub. No.: US 2020/0324390 A1
(43) Pub. Date: Oct. 15, 2020

(54) HUBBED BLADE

(71) Applicant: DISCO CORPORATION, Tokyo (JP)

(72) Inventors: Ryoji TAGUCHI, Tokyo (JP); Takashi FUKAZAWA, Tokyo (JP); Takayuki GAWAZAWA, Tokyo (JP)

(21) Appl. No.: 16/833,949

(22) Filed: Mar. 30, 2020

(30) Foreign Application Priority Data
Apr. 11, 2019 (JP) 2019-075443

(51) Int. Cl. B24D 5/12; B24D 5/16; B28D 5/02

(52) U.S. Cl. CPC B24D 5/12; H01L 21/67092; B28D 5/022; B24D 5/16

(57) ABSTRACT

A hubbed blade to be mounted on a spindle includes a circular hub having an opening formed through a center thereof, and a circular blade fixed on a side of a first side of the hub. The hub has a first raised portion and a second raised portion. The first raised portion is circular, is disposed along an outer peripheral edge of the hub, and protrudes from the first side of the hub. The second raised portion is disposed so as to surround the opening on an inner side than the first raised portion in a radial direction of the hub, and protrudes from the first side of the hub. The hub and the blade are connected together via an adhesive applied to a plurality of regions on an end face of the second raised portion.

### BACKGROUND OF THE INVENTION

### Field of the Invention

The present invention relates to a hubbed blade to be mounted on a spindle.

### Description of the Related Art

By dividing a semiconductor wafer that has a plurality of devices such as integrated circuits (ICs) or large scale integrations (LSIs), a plurality of device chips with the devices included therein, respectively, are fabricated. Further, by dividing a package substrate that has been formed by coating, with a sealing material including resin (molding resin), a plurality of device chips mounted on a substrate, a plurality of package devices is fabricated each including the device chips covered with the molding resin.

For the division of a workpiece represented by the above-described semiconductor wafer or package substrate, a cutting apparatus including a spindle with a blade mounted thereon to cut the workpieces is used, for example. The blade mounted on the spindle is rotated and cut into the workpiece, whereby the workpiece is cut. As blades for use in cutting such workpieces, there are known electroformed hub blades including a cutting blade with abrasive grains of diamond or the like fixed by a plating of nickel or the like, circular blades including a cutting blade with abrasive grains fixed with a bonding material of metal, ceramic, or resin, and the like. Upon cutting a workpiece, an appropriate blade is selected as desired according to the material and the like of the workpiece.

An electroformed hub blade is configured as an integral unit of a disk-shaped hub made of aluminum or the like and a circular cutting blade formed along an outer peripheral edge of the hub, and is mounted on a blade mount fixed on a distal end portion of a spindle which is incorporated in a cutting apparatus. On the other hand, a circular blade is mounted on a distal end portion of a spindle such that the circular blade is held between a flange portion (fixed flange) included in a blade mount and a detachable flange. As is appreciated from the foregoing, the electroformed hub blade and the circular blade are different in the manner of mounting on the spindle, and therefore the shape, dimensions and the like of the blade mount to be fixed on the spindle are also different depending on the type of the blade. Upon replacement of the circular blade for the electroformed hub blade, for example, a need arises to also replace the blade mount, resulting in blade replacement work of poor efficiency. In recent years, hubbed blades with a circular blade bonded on a disk-shaped hub have been proposed accordingly (see, for example, JP 2012-135833A). The use of such a hubbed blade enables a circular blade to be mounted on a blade mount for an electroformed hub blade, thereby obviating the replacement of the blade mount.

### SUMMARY OF THE INVENTION

The hubbed blade is manufactured by bonding the hub and the blade together via an adhesive. Upon bonding them together, the adhesive is pressed and caused to spread out between the hub and the blade, and may then spread out from a connection region between the hub and the blade. If this is the case, the adhesive sticks to an outer peripheral portion of the blade to adversely affect processing, the appearance or the like, thereby possibly lowering the quality of the hubbed blade. The spread-out adhesive is therefore removed manually, but the manufacturing efficiency of such hubbed blades is lowered by this removal work.

With the foregoing problems in view, the present invention therefore has as an object thereof the provision of a hubbed blade that can reduce such spread-out of adhesive.

In accordance with an aspect of the present invention, there is provided a hubbed blade to be mounted on a spindle. The hubbed blade includes a circular hub having an opening formed through a center thereof, and a circular blade fixed on a side of a first side of the hub. The hub has a first circular raised portion disposed along an outer peripheral edge of the hub and protruding from the first side, and a second raised portion disposed so as to surround the opening on an inner side than the first raised portion in a radial direction of the hub and protruding from the first side. The hub and the blade are connected together via an adhesive applied to a plurality of regions on an end face of the second raised portion.

Preferably, the blade has an outer peripheral edge disposed on an outer side than the outer peripheral edge of the hub in the radial direction of the hub, and an inner diameter of the blade is greater than or equal to an inner diameter of the hub. Also preferably, a blade mount including a disk-shaped flange portion, on an outer peripheral portion of which a circular raised portion is disposed, and a support shaft extending from a center of the flange portion is fixed on a distal end portion of the spindle, and the blade is held between the first raised portion of the hub and the raised portion of the flange portion by a lock nut configured to be fastenable on a distal end portion of the support shaft with the support shaft inserted in the opening of the hub.

The hubbed blade according to the aspect of the present invention includes the circular hub and the circular blade, and the hub has the first raised portion and the second raised portion. The first raised portion is circular and is disposed along the outer peripheral edge of the hub, and the second raised portion is disposed on the inner side than the first raised portion. The hub and the blade are connected together via the adhesive applied to the plurality of regions on the end face of the second raised portion. With the hubbed blade, the adhesive held between the hub and the blade also flows to regions which are not applied with the adhesive on the end face of the second raised portion upon bonding the hub and the blade together. Compared with the case where the adhesive is applied to the entirety of the end face of the second raised portion, the adhesive is hence less prone to spread out from the second raised portion, thereby suppressing the quality of the hubbed blade from being lowered.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an exploded perspective view depicting a hubbed blade according to an embodiment of the present invention;

FIG. 2 is a front view depicting a hub of the hubbed blade, in which an adhesive has been applied to the hub;

FIG. 3 is a cross-sectional view depicting the hubbed blade, in which the hub and a blade have been connected together;

FIG. 4 is a perspective view depicting a cutting apparatus that cuts workpieces with the hubbed blade; and

FIG. 5 is an exploded perspective view depicting a cutting unit on which the hubbed blade is mounted.

### DETAILED DESCRIPTION OF THE PREFERRED EMBODIMENT

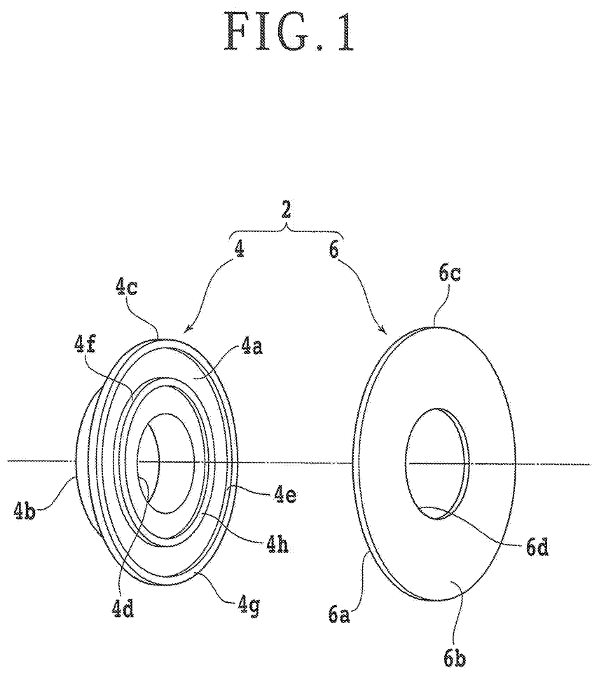

With reference to the appended drawings, a description will hereinafter be made regarding an embodiment of the present invention. First, a description will be made regarding a configuration example of a hubbed blade according to the embodiment. FIG. 1 is an exploded perspective view depicting the hubbed blade 2.

The hubbed blade 2 includes a circular hub 4 and a circular blade 6. The hub 4 is made, for example, of aluminum or the like, and has a first side 4a and a second side 4b, which are parallel to each other, and an outer peripheral edge 4c. At a center of the hub 4, a circular opening 4d is formed which extends through the hub 4 from the first side 4a to the second side 4b. On an outer peripheral portion of the hub 4, a circular first raised portion 4e is disposed which protrudes from the first side 4a toward the blade 6 along the outer peripheral edge 4c. At a region on an inner side than the first raised portion 4e in a radial direction of the hub 4, a circular second raised portion 4f is disposed apart from the first raised portion 4e and protruding from the first side 4a toward the blade 6. The first raised portion 4e and the second raised portion 4f are arranged concentrically so as to surround the opening 4d. No limitation is imposed on the shape of the second raised portion 4f, so that the second raised portion 4f may be disposed in a polygonal shape (a square shape or the like) that surrounds the opening 4d, for example. The first raised portion 4e includes a first end face 4g on an end thereof, and the second raised portion 4f includes a second end face 4h on an end thereof. The first end face 4g and the second end face 4h are formed substantially parallel to the first side 4a.

The blade 6 is fixed on a side of the first side 4a of the hub 4. The blade 6 has been formed by fixing abrasive grains, for example, of diamond, cubic boron nitride (cBN) or the like with a bonding material of metal, ceramic, resin or the like. However, no limitation is imposed on the abrasive grain and bonding material included in the blade 6, and they can be appropriately selected according to a specification or the like of the hubbed blade 2. The blade 6 has a first side 6a and a second side 6b, which are parallel to each other, and an outer peripheral edge 6c. At a center of the blade 6, a circular opening 6d is formed which extends through the blade 6 from the first side 6a to the second side 6b.

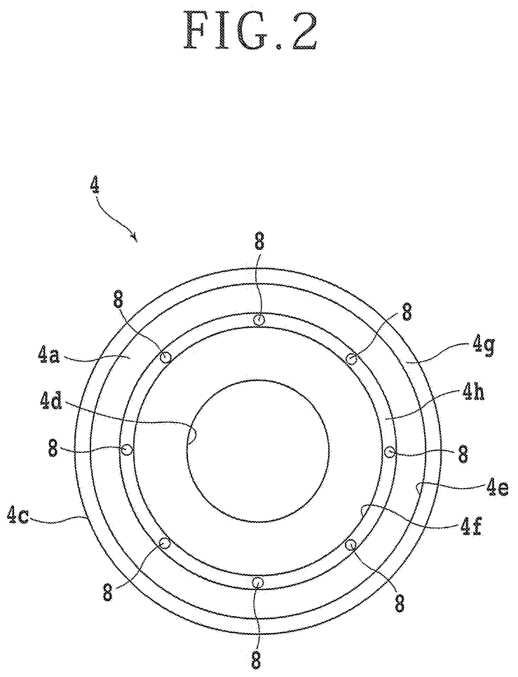

By bonding the hub 4 and the blade 6 with an adhesive, the hubbed blade 2 is obtained with the hub 4 and the blade 6 integrated together. Upon bonding the hub 4 and the blade 6 together, an adhesive is first applied to the hub 4. FIG. 2 is a front view depicting the hub 4 with the adhesive 8 applied thereto. The adhesive 8 is applied to a plurality of regions on the second end face 4h of the second raised portion 4f along a peripheral direction of the second raised portion 4f. As the adhesive 8, an epoxy resin-based adhesive can be used, for example. The plural regions on the second end face 4h, the regions having been applied with the adhesive 8, are not in contact with one another. In other words, the adhesive 8 is applied to some regions on the second end face 4h, so that regions not applied with the adhesive 8 are included in the second end face 4h. With the adhesive 8 applied on the hub 4, the first side 4a of the hub 4 and the first side 6a of the blade 6 are placed facing each other, and the hub 4 and the blade 6 are bonded together such that their central axes are coaxially aligned. As a consequence, the hub 4 and the blade 6 are connected together via the adhesive 8.

FIG. 2 depicts an example in which the adhesive 8 is applied in a form of dots at substantially equal intervals at eight locations on the second end face 4h. However, no limitation is imposed on the number, locations, shape and the like of the regions where the adhesive 8 is applied. The foregoing description is directed to the case where the adhesive 8 is applied to the hub 4. However, the adhesive 8 may be applied to the blade 6 instead. In this case, the adhesive 8 is applied to the first side 6a of the blade 6 at some regions of an area that corresponds to the second raised portion 4f of the hub 4.

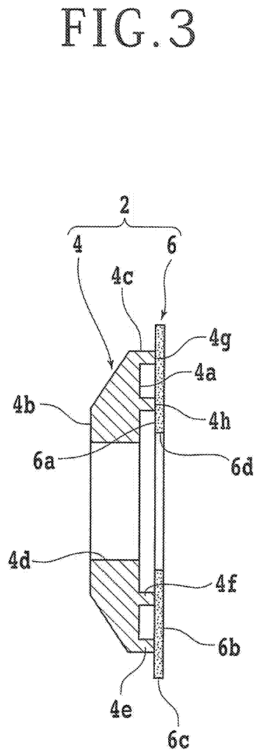

FIG. 3 is a cross-sectional view depicting the hubbed blade 2 with the hub 4 and the blade 6 connected together. The hub 4 and the blade 6 are connected together via the adhesive 8 stuck to the plural regions on the second end face 4h of the second raised portion 4f (see FIG. 2). On the other hand, no adhesive 8 is stuck on the first end face 4g of the first raised portion 4e of the hub 4. Accordingly, the first end face 4g is in contact with the blade 6 but is not bonded to the blade 6. The outer peripheral edge 6c of the blade 6 has a greater diameter than the outer peripheral edge 4c of the hub 4. When the hub 4 and the blade 6 are connected together, the outer peripheral edge 6c of the blade 6 is hence disposed on an outer side of the outer peripheral edge 4c of the hub 4 in the radial direction of the hub 4, and thus extends outwardly from the outer peripheral edge 4c. Further, the blade 6 has an inner diameter (a diameter in the opening 6d) greater than or equal to that (a diameter in the opening 4d) of the hub 4, and the opening 4d and the opening 6d are arranged concentrically.

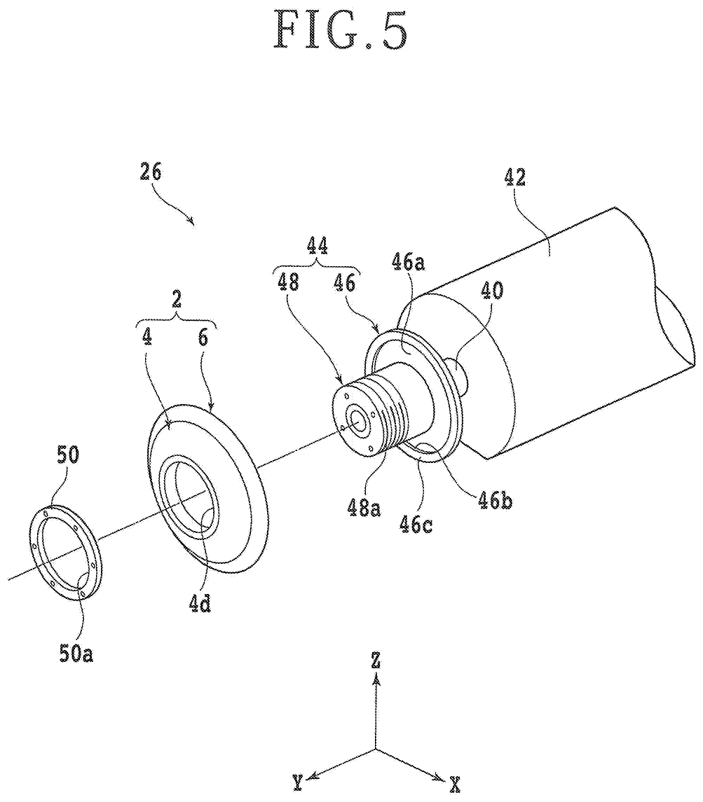

Now assume that the hub 4 and the blade 6 are connected together by applying the adhesive 8 to the entirety of the second end face 4h. The adhesive 8 is pressed and caused to spread out between the hub 4 and the blade 6. The adhesive may then spread out from the second raised portion 4f toward the outer peripheral edge 4c and the opening 4d. The spread-out adhesive 8 causes lowering the quality of the hubbed blade 2. Described specifically, if the spread-out adhesive 8 sticks to the vicinity of the outer peripheral edge 6c of the blade 6, the accuracy of processing by the hubbed blade 2 may be lowered. If the adhesive 8 sticks to the vicinity or inside of the opening 4d, on the other hand, work can be hampered upon mounting the hubbed blade 2 on a distal end portion of a spindle 40 (see FIG. 5). Further, the appearance of the hubbed blade 2 deteriorates due to the spread-out adhesive 8.

In the embodiment, the hub 4 and the blade 6 are therefore connected together via the adhesive 8 stuck on the plural regions on the second end face 4h (see FIG. 2) as described above. In this manner, upon bonding the hub 4 and the blade 6 together, the adhesive 8 applied between the hub 4 and the blade 6 also flows to the regions on the second end face 4h, the regions having not been applied with the adhesive 8. Compared with the case where the adhesive 8 is applied to the entirety of the second end face 4h, the adhesive 8 is less prone to spread out from the second raised portion 4f, thereby suppressing the quality of the hubbed blade 2 from being lowered. The first raised portion 4e is formed on and along the outer peripheral portion of the hub 4. The adhesive 8 is therefore prevented by the first raised portion 4e from sticking to the vicinity of the outer peripheral edge 6c of the blade 6 even if the adhesive 8 spreads out from the second end face 4h toward the outer peripheral edge 4c.

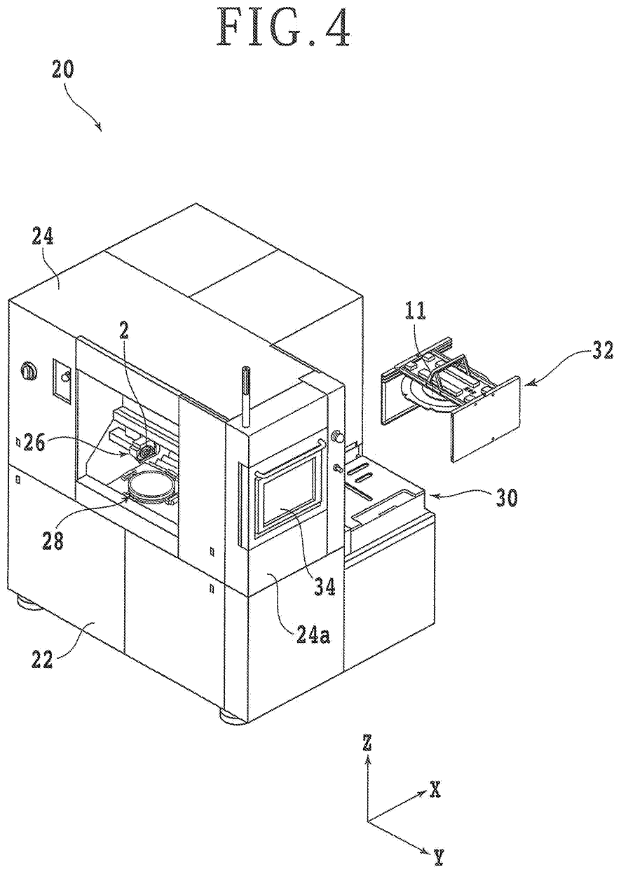

Next, a description will be made regarding a configuration example of a cutting apparatus that cuts workpieces with the hubbed blade 2. FIG. 4 is a perspective view depicting the cutting apparatus 20 that cuts the workpieces 11. It is to be noted that for the sake of simplification of depiction, FIG. 4 presents only one of the workpieces 11. Examples of the workpieces 11 to be cut by the cutting apparatus 20 include semiconductor wafers each including devices such as ICs or LSIs, and package substrates such as chip size package (CSP) substrates and quad flat non-leaded package (QFN) substrates. However, no limitation is imposed on the kind, material, shape, structure, size and the like of the workpieces 11. For example, the workpieces 11 may be substrates made of ceramic, resin, metal or the like.

The cutting apparatus 20 includes a base 22 that supports various constituent elements, and over the base 22, a cover 24 is disposed enclosing the base on a side of its upper surface. Inside the cover 24, a space is defined to perform processing of each workpiece 11. In this space, a cutting unit 26 is disposed to allow mounting of the hubbed blade 2. The cutting unit 26 is connected to moving mechanisms (not depicted), which move the cutting unit 26 along front and rear directions (Y-axis direction, indexing feed direction) and vertical directions (Z-axis direction).

Below the cutting unit 26, a chuck table 28 is disposed to hold the workpiece 11. The chuck table 28 has a top surface, which constitutes a holding surface that holds the workpiece 11. A suction source (not depicted) is connected to the holding surface via a suction line (not depicted). By applying a negative pressure of the suction source to the holding surface with the workpiece 11 placed on the chuck table 28, the workpiece 11 is held under suction by the chuck table 28. The chuck table 28 is connected to a moving mechanism (not depicted), which moves the chuck table 28 in left and right directions (X-axis direction, processing feed direction). The chuck table 28 is also connected to a rotating mechanism (not depicted), which rotates the chuck table 28 about an axis of rotation that is substantially parallel to the vertical directions (Z-axis direction).

In addition, a cassette elevator 30 is disposed in a front corner section of the base 22. On a top surface of the cassette elevator 30, a cassette 32 that can accommodate the workpieces 11 is mounted. The cassette elevator 30 is configured to be movable up and down, and the height (position in the vertical directions) of the cassette 32 is adjusted such that desired one of the workpieces 11 is appropriately carried out and carried in.

On a side of the front side 24a of the cover 24, a touch panel monitor 34 is disposed as a user interface. Similarly to the cutting unit 26, the moving mechanisms connected to the cutting unit 26, the chuck table 28, the moving mechanism and rotating mechanism connected to the chuck table 28, the cassette elevator 30 and the like, the monitor 34 is also connected to a control unit (not depicted) that controls operations of the individual constituent elements of the cutting apparatus 20.

FIG. 5 is an exploded perspective view of the cutting unit 26. The cutting unit 26 includes the spindle 40 disposed along the Y-axis direction. The spindle 40 is accommodated in a cylindrical spindle housing 42. The spindle 40 is exposed to an outside of the spindle housing 42 at the distal end portion (an end portion) thereof, and a blade mount 44 is fixed on the distal end portion of the spindle 40. To a side of an opposite end (proximal end) of the spindle 40, a motor (not depicted) is connected to rotate the spindle 40.

The blade mount 44 includes a disk-shaped flange portion (fixed flange) 46, and a support shaft 48 extending from a central portion of a surface 46a of the flange portion 46. On a side of the surface 46a of an outer peripheral portion of the flange 46, a circular raised portion 46b is disposed which protrudes from the surface 46a. The raised portion 46b is formed at a position and in a shape corresponding to the first raised portion 4e (see FIG. 1, etc.) of the hubbed blade 2. Further, the raised portion 46b includes an end face 46c on an end thereof, and the end face 46c is formed substantially parallel to the end surface 46a. The support shaft 48 is formed in a cylindrical shape, and a thread ridge 48a is formed on an outer peripheral surface of a distal end portion of the support shaft 48. When the support shaft 48 is inserted into the opening 4d of the hub 4 of the hubbed blade 2, the hubbed blade 2 is mounted on the blade mount 44.

On the distal end portion of the support shaft 48, a circular lock nut 50 is fastened. Through a center of the lock nut 50, a circular opening 50a of a diameter corresponding to that of the support shaft 48 is formed. In an inner peripheral surface of the opening 50a, a thread groove (not depicted) is formed which corresponds to the thread ridge 48a formed on the support shaft 48. When the lock nut 50 is fastened on the thread ridge 48a of the support shaft 48 with the support shaft 48 inserted in the opening 4d of the hub 4, the hubbed blade 2 is held by the first raised portion 4e (see FIG. 1, etc.) of the hub 4 and the raised portion 46b of the flange portion 46. As a consequence, the blade 6 is fixed on the distal end portion of the spindle 40. As mentioned above, the inner diameter of the blade 6 (the diameter of the opening 6d) is greater than or equal to the inner diameter of the hub 4 (the diameter of the opening 4d), and the opening 4d and the opening 6d are arranged concentrically. Upon insertion of the support shaft 48 into the opening 4d of the hub 4, the blade 6 therefore remains out of contact with the support shaft 48, so that the mounting of the hubbed blade 2 is not interfered with.

When the spindle 40 is rotated with the hubbed blade 2 mounted on the cutting unit 26, the hubbed blade 2 rotates about an axis of the spindle 40. By then allowing the blade 6 to cut into the workpiece 11 held on the chuck table 28 (see FIG. 4), the workpiece 11 is cut.

As described above, the hubbed blade 2 according to the embodiment includes the circular hub 4 and the circular blade 6, and the hub 4 has the first raised portion 4e and the second raised portion 4f. The first raised portion 4e is circular and is disposed along the outer peripheral edge of the hub 4, and the second raised portion 4f is disposed on the inner side than the first raised portion 4e. The hub 4 and the blade 6 are connected together via the adhesive 8 stuck on the plurality of regions on the second end face 4h of the second raised portion 4f. With the hubbed blade 2, the adhesive 8 applied between the hub 4 and the blade 6 also flows to the regions which are not applied with the adhesive 8 on the second end face 4h upon bonding the hub 4 and the blade 6 together. Compared with the case where the adhesive 8 is applied to the entirety of the end face of the second raised portion 4f, the adhesive 8 is hence less prone to spread out from the second raised portion 4f, thereby suppressing the quality of the hubbed blade 2 from being lowered.

It should be noted that the structure, method and the like relating to the above-described embodiment can be practiced with modifications as needed to an extent not departing from the scope of the object of the present invention.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A hubbed blade to be mounted on a spindle, comprising:
a circular hub having an opening formed through a center thereof; and
a circular blade fixed on a side of a first side of the hub, wherein
the hub has a first circular raised portion disposed along an outer peripheral edge of the hub and protruding from the first side, and a second raised portion disposed so as to surround the opening on an inner side than the first raised portion in a radial direction of the hub and protruding from the first side, and
the hub and the blade are connected together via an adhesive applied to a plurality of regions on an end face of the second raised portion.

2. The hubbed blade according to claim 1, wherein
the blade has an outer peripheral edge disposed on an outer side than the outer peripheral edge of the hub in the radial direction of the hub, and
an inner diameter of the blade is greater than or equal to an inner diameter of the hub.

3. The hubbed blade according to claim 1, wherein
a blade mount including a disk-shaped flange portion, on an outer peripheral portion of which a circular raised portion is disposed, and a support shaft extending from a center of the flange portion is fixed on a distal end portion of the spindle, and
the blade is held between the first raised portion of the hub and the raised portion of the flange portion by a lock nut configured to be fastenable on a distal end portion of the support shaft with the support shaft inserted in the opening of the hub.
